(19) United States
(12) Patent Application Publication
(10) Pub. No.: US 2007/0025086 A1
(43) Pub. Date: Feb. 1, 2007

(54) ELECTRONIC DEVICE WITH SLIDING TYPE HEATSINK

(75) Inventors: Chien-Chiang Huang, Taipei (TW); Tsung-Hsien Li, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ASUSTEK COMPUTER INC., Taipei (TW)

(21) Appl. No.: 11/462,715

(22) Filed: Aug. 7, 2006

(30) Foreign Application Priority Data
Jul. 26, 2005 (TW) 94125213

(51) Int. Cl. H05K 7/20

(52) U.S. Cl. 361/704

(57) ABSTRACT

An electronic device with sliding type heatsink including a printed circuit board, a heat dissipation module and at least a guide post is provided. Wherein, a heat-generating element is disposed on the printed circuit board, and the heat dissipation module is disposed on the heat-generating element. The heat dissipation module includes at least an elastic element which has an assembly hole. The assembly hole has a guide part and a first fixing part. Besides, the guide post protrudes from the printed circuit board and is located in the assembly hole. A side of the guide post has a groove. When the heat dissipation module moves a suited distance, the groove slides into the first fixing part from the guide part that makes the guide post fix with the first fixing part. Thus, the heat dissipation module can tightly fix on the heat-generating element.

### BACKGROUND OF THE INVENTION

1. Field of Invention

The present invention relates to an electronic device. More particularly, the present invention relates to an electronic device with heat dissipation module.

2. Description of Related Art

Recently, along with the rapid advance of technology, the calculation speed of electronic devices inside host computers is increased continuously. The heat-generating efficiency of electronic devices also increases constantly along with the advance of calculation speed of electronic devices. To prevent overheating the electronic devices inside the host computers that may lead to a temporary or permanent failure of the electronic devices, the electronic devices are required having efficient heat dissipation so as to function properly.

FIG. 1 is a stereogram illustrating a conventional electronic device. Referring to FIG. 1, the conventional electronic device 100 has a printed circuit board 110, a heat dissipation module 120, a heat-generating element 130, a locking backboard 140, a plurality of elastic elements 150 and a plurality of screws 160. Wherein, the heat-generating element 130 is disposed on the printed circuit board 110, and the heat dissipation module 120 is fixed on a contact surface 130a of the heat-generating element 130. In addition, the locking backboard 140 which has a plurality of bolt posts 142 is disposed under the printed circuit board 110. In other words, the bolt posts 142 protrude from the printed circuit board 110. Moreover, the elastic element 150 has a plurality of through holes 152 and is riveted at one side of the heat dissipation module 120.

In addition, the heat dissipation module 120 can be fixed on the heat-generating element 130 successfully by passing at least four screws 160 through the through holes 152 on the elastic elements 150 and screwing them down to the bolt posts 142 respectively, then the elastic elements 150 will give the heat dissipation module 120 a downward pressure so that the heat dissipation module 120 may make close contact with the heat-generating element 130.

When the electronic device 100 is in operation, the heat-generating element 130 is in the status of high temperature, by making contact with the heat dissipation module 120, the heat-generating element 130 may transfer its heat to the heat dissipation module 120 through heat conduction, and then the temperature of the heat-generating element 130 may be reduced through heat convection between the heat dissipation module 120 and the air around it. Thereby, the electronic device 100 will not be overheated.

However, to secure the heat dissipation module on the heat-generating element, a plurality of screws has to be fixed on the corresponding bolt posts so that the elastic element may supply a downward pressure to the heat dissipation module as described above. Thus, a lot of time will be spent over the aforesaid fixing procedure. Hence, how to reduce the fixing time for securing the heat dissipation module on the heat-generating element is a very important task. Moreover, if the degree of tightness between each screw and its corresponding bolt post is different, the downward pressure supplied to the heat dissipation module by the elastic elements disposed at each side of the heat dissipation module will be different and this will cause uneven pressure on the heat dissipation module fixed on the heat-generating element. As a result, not only the heat dissipation capability of the heat dissipation module on the heat-generating element but also the performance of the electronic device will be affected, so that how to make the heat dissipation module receives even pressure when it is fixed on the heat-generating element is another important issue.

### SUMMARY OF THE INVENTION

Accordingly, the present invention is directed to provide an electronic device; within this electronic device the heat dissipation module can be secured on the heat-generating element through simple operation to reduce assembly time.

To achieve the aforesaid feature, the present invention provides an electronic device with sliding type heatsink, including a printed circuit board, a heat dissipation module and at least a guide post. Wherein, a heat-generating element is disposed on the printed circuit board, and the heat dissipation module is disposed on the heat-generating element. The heat dissipation module is disposed with at least an elastic element which has an assembly hole, and the assembly hole has a guide part and a first fixing part. In addition, the guide post protrudes from the printed circuit board and passes through the assembly hole, and there is a groove at one side of the guide post. Wherein, the guide post has a first external diameter, and a corresponding second external diameter at the groove, the second external diameter is smaller than the first external diameter. When the heat dissipation module moves a suited distance, the groove will slide into the first fixing part from the guide part so that the guide post fastens on the first fixing part. Wherein, a first internal diameter of the guide part is greater than a second internal diameter of the first fixing part, and the second internal diameter is substantially equal to the second external diameter.

According to an embodiment of the present invention, the assembly hole is, for example, a gourd-shaped hole. Wherein, the guide part is a fist hole, the first fixing part is a second hole, and the first hole is joined to the second hole to form a gourd-shaped hole.

According to an embodiment of the present invention, the electronic device, for example, further includes a guide post bracket, and the guide post is fixed on the guide post bracket. Wherein, the guide post bracket is adjacent to a surface of the printed circuit board, i.e. the guide post passes through the printed circuit board.

According to an embodiment of the present invention, the electronic device further includes, for example, at least a screw and a bolt post. The screw is used for fastening the heat dissipation module to the bolt post. Wherein, the bolt post is, for example, fixed on the guide post bracket and is protruding from the printed circuit board.

According to an embodiment of the present invention, the elastic element is, for example, an elastic metal.

According to an embodiment of the present invention, the heat dissipation module includes, for example, a base, a second fixing part and at least a heatsink fin. Wherein, the heatsink fin is located at the first side of the base, and a second side of the base is opposite the first side and meets the heat-generating element. In addition, the second fixing part is at one side of the base, and the elastic element is fixed to the second fixing part.

According to an embodiment of the present invention, the assembly hole is, for example, located at a curving part of the elastic element. The guide part of the assembly hole is closer to the printed circuit board than the first fixing part of the assembly hole. When the groove slides into the first fixing part from the guide part, the guide post will force the elastic element to bend toward the printed circuit board to fix the heat dissipation module.

As afore-mentioned, in an electronic device of the present invention, the heat dissipation module only needs to slide a suited distance, so that with the interaction between the elastic element allocated on the heat dissipation module and the guide post allocated on the guide post bracket, the elastic element on the heat dissipation module may supply a downward pressure on the heat dissipation module. Accordingly, the heat dissipation module and the heat-generating element may maintain a status of close contact. In addition, the heat dissipation module may be fastened to a bolt post with only one screw; accordingly, the relative location between the elastic element and the guide post may be fixed so that the elastic element may maintain a status of pressing downward constantly; the heatsink may also be in close contact with the heat-generating element. Therefore, it is possible to secure the heat dissipation module to the heat-generating element with a simple operation to reduce assembly time. Moreover, the amount of screws used can be decreased according to the present invention.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a stereogram illustrating a conventional electronic device.

FIG. 2 is a comprehensive diagram illustrating an electronic device according to exemplary embodiments of the present invention.

FIG. 3 is a stereogram of the electronic device in FIG. 2.

FIG. 4 is a stereogram of the elastic element in FIG. 3.

FIG. 5 is a stereogram of the heat dissipation module in FIG. 3.

FIG. 6a is a top view of the heat dissipation module in FIG. 3 when it is not fixed with the heat-generating element closely.

FIG. 6b is an enlarged profile view of the heat dissipation module in FIG. 6a cut along line A-A′.

FIG. 7a is a top view of the heat dissipation module in FIG. 3 after it is fixed with the heat-generating element closely.

FIG. 7b is an enlarged profile view of the heat dissipation module in FIG. 7acut along line A-A′.

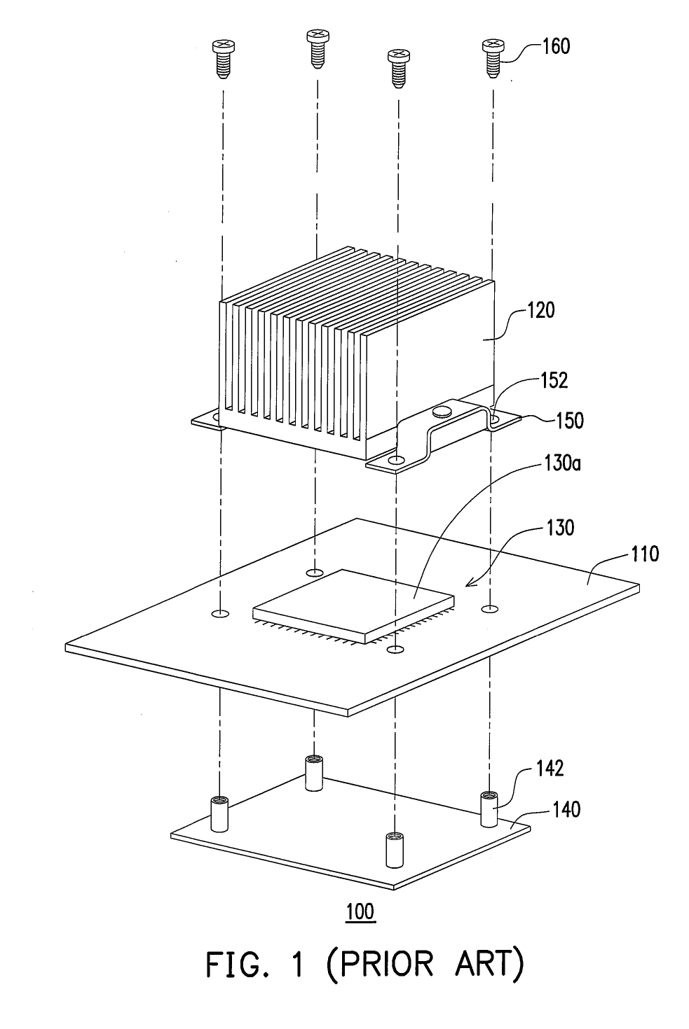

### DESCRIPTION OF EMBODIMENTS

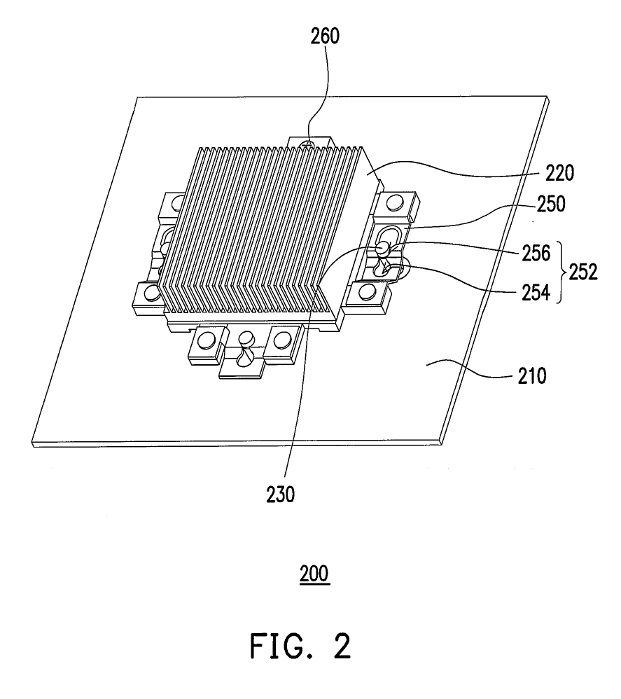

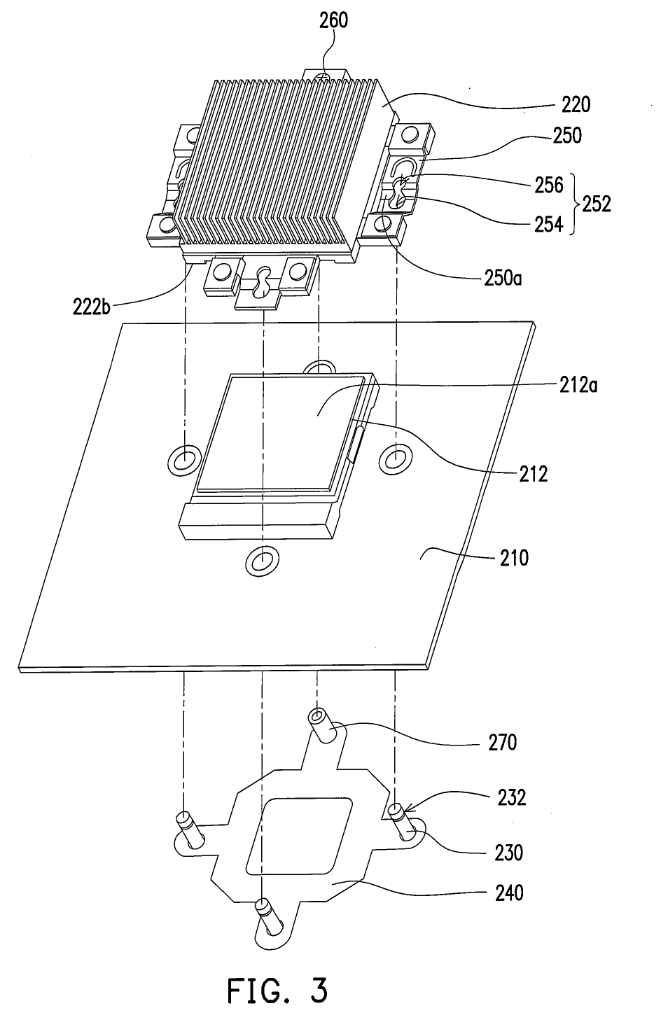

FIG. 2 is a comprehensive diagram illustrating an electronic device according to the exemplary embodiments of the present invention and FIG. 3 is a stereogram of the electronic device in FIG. 2. Referring to both FIG. 2 and FIG. 3, in the present embodiment, the electronic device 200 includes a printed circuit board 210, a heat dissipation module 220 and one or multiple guide posts 230. Wherein, a heat-generating element 212 is disposed on the printed circuit board 210, the heat-generating element 212 is, for example, a Central Processing Unit (CPU) of a computer or a North Bridge chip and so on. In addition, the heat dissipation module 220 is located on the heat-generating element 212 and is in contact with an contact surface 212a of the heat-generating element 212. The heat dissipation module 220 is used for dissipating the heat inside the heat-generating element 212 so as to reduce the temperature of the heat-generating element 212. As a result, the heat-generating element 212 is prevented from being temporarily or permanently failed because of the overheating which may further affect the operation of the electronic device 200.

The electronic device 200 further includes, for example, a guide post bracket 240 used for fixing itself with the heat dissipation module and further allowing the heat dissipation module 220 to make contact with the heat-generating element 212 closely. With the fixture between the heat dissipation module 220 and the guide post bracket 240, it will avoid the direct fixture between the heat dissipation module 220 and the printed circuit board 210 which may cause the printed circuit board 210 to be destroyed or distorted. Wherein, the guide post bracket 240 is adjacent to a surface of the printed circuit board 210 (the bottom side of the printed circuit board 210). In addition, the guide post 230 is fixed on the guide post bracket 240, that is, the guide post 230 passes through the printed circuit board 210. Certainly, the guide post 230 may also be fastened directly on the printed circuit board 210 or may be fixed with other supporting structures.

In addition, the heat dissipation module 220 is in close contact with the heat-generating element 212 through the aforementioned guide post 230 and one or multiple elastic elements 250 allocated on the heat dissipation module 220. The elastic elements 250 are, for example, elastic metal. Wherein, the location where the elastic element 250 is located on the heat dissipation module 220 is opposite to the guide post 230 on the guide post bracket 240; with the interaction between the guide post 230 and the elastic element 250, the elastic element 250 may supply a downward pressure on the heat dissipation module 220 to keep the heat dissipation module 220 and the heat-generating element 212 in close contact.

FIG. 4 is a stereogram of the elastic element in FIG. 3. Referring to FIG. 4, the elastic element 250 has an assembly hole 252 which has a guide part 254 and a first fixing part 256. Wherein, the guide part 254 has a first internal diameter (not shown), and the first fixing part 256 has a second internal diameter (not shown), the first internal diameter of the guide part 254 is greater than the second internal diameter of the first fixing part 256. Moreover, there may be formed a curving part 250a on the elastic element 250 where the smallest aperture part 252a of the assembly hole 252 is located to place two bigger apertures of the assembly hole at different planes, for example, the bigger aperture of the guide part 254 is at the first platform P1 and the bigger aperture of the first fixing part 256 is at the second platform P2, wherein the guide part 254 is closer to the printed circuit board 210 than the first fixing part 256.

As described, the guide part 254 is, for example, a first hole, and the first fixing part 256 is, for example, a second hole; the first hole is joined with the second hole to form a gourd-shaped hole. On the other hand, the guide post 230 protrudes from the printed circuit board 210 and is located in the assembly hole 252. Wherein, there is a groove 232 at one side of the guide post 230 and which is formed by machining the side of the guide post 230 by, for example, cutting a snick of suited depth at the side of the guide post 230, and the groove 232 is joined with the first fixing part 256. In addition, the guide post 230 has a first external diameter (not shown), and the guide post 230 has a second external diameter (not shown) at the groove 232, the second external diameter is smaller than the first external diameter. The second external diameter is, for example, the smaller external diameter generated by machining the guide post 230, wherein the second external diameter is substantially equal to the second internal diameter of the first fixing part 256.

Next, the allocation pattern of the elastic element 250 on the heat dissipation module 220 and the interaction between the guide post 230 and the elastic element 250 will be described in detail.

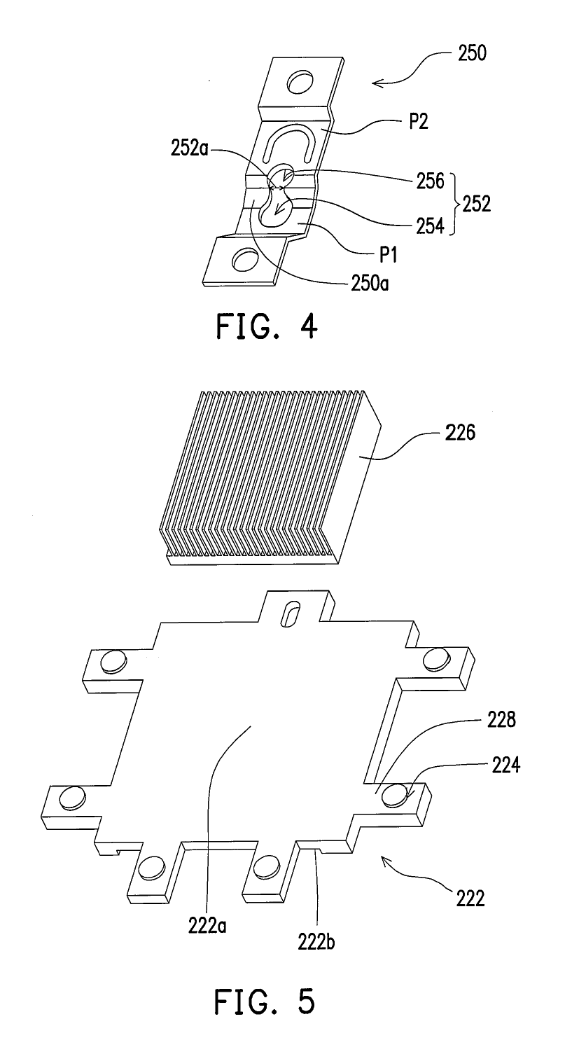

FIG. 5 is a stereogram of the heat dissipation module in FIG. 3. Referring to both FIGS. 3 and 5, the heat dissipation module 220 includes, for example, a base 222, a second fixing part 224 and one or multiple heatsink fins 226. Wherein, a side of the base 222 has a plurality of bulgy parts 228, the second fixing part 224 is at the bulgy part 228, and the elastic element 250 is assembled between two adjacent bulgy parts 228. The operation to dispose the elastic element 250 on the heat dissipation module 220 may be achieved by riveting the elastic element 250 to the second fixing part 224 on the bulgy part 228. In addition, the heatsink fins 226 are located at a first side 222a of the base 222, and a second side 222b of the base 222 is opposite the first side 222a and is in contact with the surface of the heat-generating element 212, wherein the material of the base 222 and the heatsink fins 226 are a material with better heat conductibility, for example, copper or aluminum.

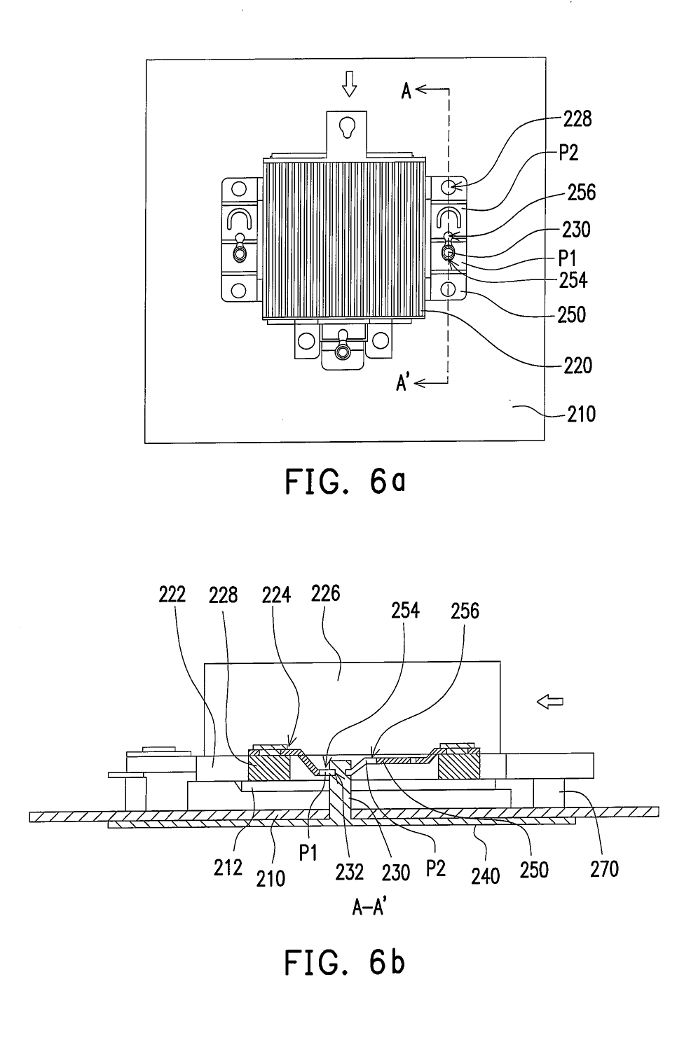

In the embodiment of the present invention, the heat dissipation module 220 and the heat-generating element 212 may maintain a status of close contact through the interaction between the guide post 230 and the elastic element 250. The interaction between the guide post 230 and the elastic element 250 will be further described here. FIG. 6a is a top view of the heat dissipation module in FIG. 3 when it is not in close contact with the heat-generating element. FIG. 6b is an enlarged profile view of the heat dissipation module in FIG. 6a cut along line A-A′. Referring to both FIGS. 6a and 6b, when the heat dissipation module 220 is not in close contact with the heat-generating element 212, the guide post 230 is located in the guide part 254 of the assembly hole 252. Wherein, the second external diameter of the guide post 230 is smaller than the first internal diameter of the guide part 254, so that the guide post 230 and the guide part 254 are in a status of loose assembly. Thus, the guide post 230 may be fastened easily into the first fixing part 256 from the guide part 254 by supplying only a level power to the heat dissipation module 220, the aforesaid process will be described in detail below.

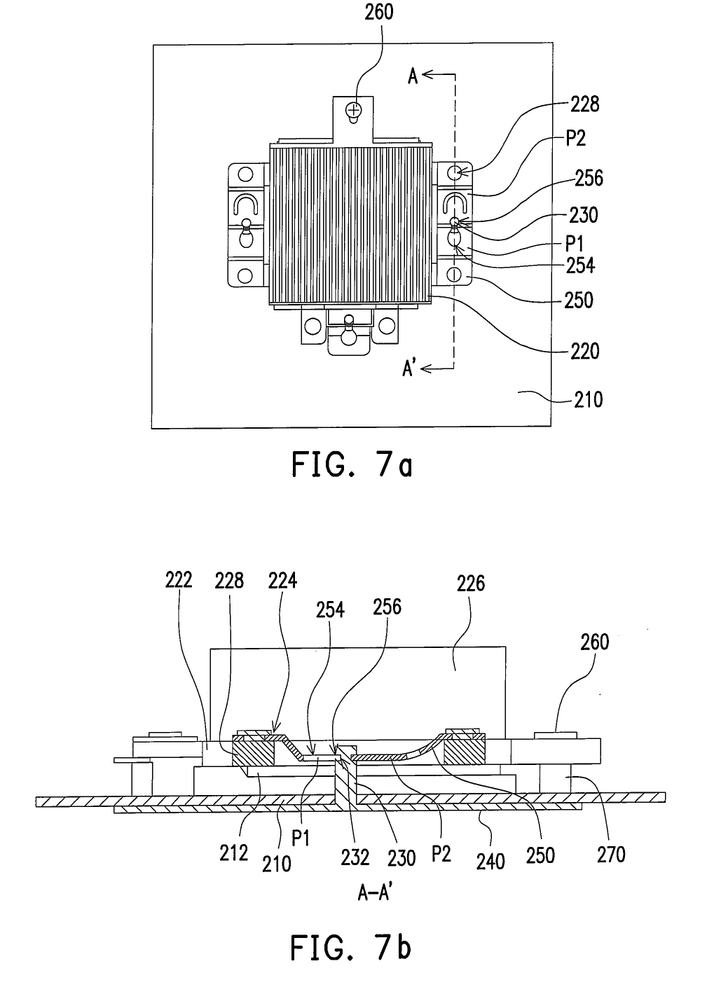

Refer to FIG. 7a which is a top view of the heat dissipation module in FIG. 3 after it is fixed with the heat-generating element closely. As illustrated in the figure, after a level power is supplied to the heat dissipation module 220 to move the heat dissipation module 220 a suited distance, the guide post 230 located in the assembly hole will be fastened into the first fixing part 256 from the guide part 254. Here, the second external diameter of the guide post 230 is equal to the second internal diameter of the first fixing part 256, thus the guide post 230 and the first fixing part 256 are in a status of tight assembly. Next, refer to FIG. 7b which is an enlarged profile view of the heat dissipation module in FIG. 7a cut along line A-A′. As illustrated in the figure, during the process of fastening the guide post 230 into the first fixing part 256 from the guide part 254, since the guide part 254 and the first fixing part 256 are at the first platform P1 and the second platform P2 of the step changes respectively (as shown in FIG. 4), and the guide part 254 is closer to the printed circuit board 210 than the first fixing part 256 (as shown in FIG. 6b), when the groove 232 is sliding into the first fixing part 256 from the guide part 254, the guide post 230 will force the elastic element 250 to bend towards the printed circuit board 210 and supply a downward pressure on the heat dissipation module 220, so that the heat dissipation module 220 and the heat-generating element 212 may stay in close contact.

After fastening the guide post 230 on the first fixing part 256, to keep the guide post 230 fixed to the first fixing part 256, one screw 260 may be used to fasten a side of the heat dissipation module 220 on a bolt post 270 on the guide post bracket 240, wherein the bolt post 270 protrudes from the printed circuit board 210. Thereby the relative locations of the elastic element 250 and the guide post 230 are fixed, so that the elastic element 250 may keep pressing downwards, and the heatsink may also be able to maintain close contact with the heat-generating element.

According to the present embodiment, only the heat dissipation module 220 receiving a downwards pressure from an elastic element 250 by the interaction between the elastic element 250 and a guide post 230 is described. In the present invention, a plurality of elastic elements 250 and corresponding guide posts 230 may be used to supply the downward pressure to the heat dissipation module 220 to keep the heat dissipation module 220 and the heat-generating element 212 in contact with each other closely. The procedure of the interaction between a plurality of elastic elements 250 and corresponding guide posts 230 is identical to the description of the present embodiment and will not be described again.

In overview, in an electronic device of the present invention, the heat dissipation module only needs to slide a suited distance to allow the elastic element on the heat dissipation module supplying a downward pressure to the heat dissipation module through the interaction between the elastic element disposed on the heat dissipation module and the guide post disposed on the guide post bracket, thus the heat dissipation module and the heat-generating element may stay in close contact. Moreover, the heat dissipation module may be fixed to a bolt post with only one screw, so that the relative positions between the elastic element and the guide post are fixed and which allows the elastic element to press downwards constantly and the heatsink to stay in close contact with the heat-generating element. Accordingly, the heat dissipation module may be secured on the heat-generating element with simple operation to reduce assembly time. In other words, the quantity of screws used and the time spent on positioning the screws in the present invention are saved.

In addition, in the conventional procedure to fix a plurality of screws to the bolt posts to allow the heat dissipation module to be fixed to the heat-generating element with elastic elements, if the degree of tightness of between each screw and its corresponding bolt post is different, the heat dissipation module fixed on the heat-generating element will be under uneven pressure and this may further affect the heat dissipation capability of the heat dissipation module on the heat-generating element and the performance of the electronic device. However, in the electronic device of the present invention, the heat dissipation module is fixed on the heat-generating element through the interaction between the elastic element and the guide post, thus the heat dissipation module fixed on the heat-generating element in the present invention will receive even pressure and which allows the heat dissipation module has better heat dissipation performance on the heat-generating element and further enhance the overall quality of the electronic device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An electronic device with sliding type heatsink, comprising:
a printed circuit board on which a heat-generating element is disposed;
a heat dissipation module located on the heat-generating element and disposed with at least an elastic element having an assembly hole, wherein the assembly hole has a guide part and a first fixing part; and
at least a guide post protruding from the printed circuit board and passing through the assembly hole, there is a groove at one side of the guide post, the guide post has a first external diameter, and the guide post has a second external diameter opposite the groove, the second external diameter is smaller than the first external diameter, the heat dissipation module slides a distance and fastens the first fixing part into the groove;
Wherein a first internal diameter of the guide post is greater than a second internal diameter of the first fixing part, and the second internal diameter is substantially equal to the second external diameter.

2. The electronic device with sliding type heatsink as claimed in claim 1, wherein the assembly hole is a gourd-shaped hole, the guide part is a first hole, the first fixing part is a second hole, and the first hole is joined partially with the second hole to form the gourd-shaped hole.

3. The electronic device with sliding type heatsink as claimed in claim 1 further includes a guide post bracket, the guide post is fixed to the guide post bracket, the guide post bracket is adjacent to a surface of the printed circuit board, and the guide post passes through the printed circuit board.

4. The electronic device with sliding type heatsink as claimed in claim 1 further includes at least a screw and a bolt post, the screw secures the heat dissipation module to the bolt post, and the bolt post protrudes from the printed circuit board.

5. The electronic device with sliding type heatsink as claimed in claim 4, wherein the bolt post is fixed on the guide post bracket.

6. The electronic device with sliding type heatsink as claimed in claim 1, wherein the elastic element is an elastic metal.

7. The electronic device with sliding type heatsink as claimed in claim 1, wherein the heat dissipation module includes a base, a second fixing part and at least a heatsink fin, the heatsink fin is located at a first side of the base, a second side of the base is opposite the first side and is in contact with the heat-generating element, the second fixing part is located at one side of the base, and the elastic element is fixed to the second fixing part.

8. The electronic device with sliding type heatsink as claimed in claim 1, wherein the assembly hole is located at a curving part of the elastic element, and the guide part is closer to the printed circuit board than the first fixing part, when the groove slides into the first fixing part from the guide part, the guide post forces the elastic element to bend towards the printed circuit board to fix with the heat dissipation module.
